(19) United States
(12) Patent Application Publication
(10) Pub. No.: US 2021/0253441 A1
(43) Pub. Date: Aug. 19, 2021

(54) PRINTABLE AMMONIUM-BASED CHALCOGENOMETALATE FLUIDS WITH DOPANTS

(71) Applicant: Hewlett-Packard Development Company, L.P., Spring, TX (US)

(72) Inventors: Robert Ionescu, Palo Alto, CA (US); Helen A. Holder, Palo Alto, CA (US); Jarrid Wittkopf, Palo Alto, CA (US)

(73) Assignee: Hewlett-Packard Development Company, L.P., Spring, TX (US)

(21) Appl. No.: 17/262,353

(22) PCT Filed: Nov. 8, 2018
(86) PCT No.: PCT/US2018/059869

§ 371 Date: Jan. 22, 2021

(51) Int. Cl. C01G 41/00; C01G 39/00; C09D 11/38; H01L 21/02; B41J 2/05

(52) U.S. Cl. CPC C01G 41/006; C01G 39/006; B41J 2/05; H01L 21/02568; H01L 21/02628; C09D 11/38

(57) ABSTRACT

A printable ammonium-based chalcogenometalate fluid may include an ammonium-based chalcogenometalate precursor; an aqueous solvent; water; and a dopant; wherein, in the presence of heat, the printable ammonium-based chalcogenometalate fluid dissipates to form a transition metal dichalcogenide having the form MX2 with the dopant distributed therethrough.

### BACKGROUND

A semiconductor refers to any material that has an electrical conductivity between a conductor and an insulator. Such semiconductors are used in various applications including field effect transistors (FETs), optoelectronics, photodetectors, phototransistors, photosensors, photovoltaic cells and light-emitting diodes (LEDs). A two-dimensional (2D) semiconductor is a semiconductor having a thickness on the atomic scale.

### BRIEF DESCRIPTION OF THE DRAWINGS

The accompanying drawings illustrate various examples of the principles described herein and are part of the specification. The illustrated examples are given merely for illustration, and do not limit the scope of the claims.

FIG. 1 is a block diagram of a printable ammonium-based chalcogenometalate fluid according to an example of the principles described herein.

FIG. 2 is a flowchart showing a method according to an example of the principles described herein.

FIG. 3 is a block diagram of a printing fluid cartridge according to an example of the principles described herein.

FIG. 4 is a block diagram of a process flow used to form a semiconductor device according to an example of the principles described herein.

Throughout the drawings, identical reference numbers designate similar, but not necessarily identical, elements. The figures are not necessarily to scale, and the size of some parts may be exaggerated to more clearly illustrate the example shown. Moreover, the drawings provide examples and/or implementations consistent with the description; however, the description is not limited to the examples and/or implementations provided in the drawings.

### DETAILED DESCRIPTION

A semiconductor refers to any material that has an electrical conductivity between a conductor and an insulator. Such semiconductors are used in various applications including field effect transistors (FETs), optoelectronics, photodetectors, phototransistors, photosensors, photovoltaic cells and light-emitting diodes (LEDs). A two-dimensional (2D) semiconductor is a semiconductor with a thickness on the atomic scale. 2D semiconductors may be used in components for next generation electronics that have reduced form factors, for example.

One such material that is used in these 2D semiconductors is a transition metal dichalcogenide (TMD) which is a combination of a transition metal and a chalcogen and has the form MX₂. As described herein, such 2D semiconductors offer great potential in improving electronic device functionality. For example, poor energy efficiency in optoelectronics can be greatly improved using 2D semiconductive materials that have direct bandgap in the visible light. Unlike the indirect bandgap of silicon, a 2D layered semiconductor has a direct bandgap single-layer. This direct bandgap is effective and relevant in light emission applications and for use with other light-based devices. In another example, transistors formed using 2D layered semiconductors provide high electron mobility, provide a high on/off ratio, and facilitate transparent ultra-thin devices.

While semiconductors, and 2D semiconductors in particular, have undoubtedly advanced electrical and electronic developments in general and will inevitably continue to do so, some characteristics impede their more complete implementation. For example, manufacturing these 2D semiconductors can rely on a chemical vapor deposition (CVD) system that uses powder precursors, specifically oxides such as molybdenum trioxide (MoO3) and tungsten trioxide (WO3). These oxides result in non-uniform growth of the semiconductive material. This non-uniform growth may reduce the certainty of semiconductor shape and size, thus reducing the semiconductor's practical implementation. Moreover, CVD processes are based on nucleation, which can include numerous heating cycles which are dirty and time consuming. For example, some heating cycles may take between 2-3 hours. In some cases, such as for the manufacturing of field effect transistors, the manufacturing is performed in a clean room. As a result of the use of the clean rooms, the complexity and cost in manufacturing these field effect transistors is increased. For example, CVD processes can implement a quartz tube which is to be cleaned and maintained after the CVD operation for proper operation and manufacturing. These complications are exacerbated if a heterogeneous structural stack of these semiconductors is formed, which can include multiple CVD operations.

The present specification describes a printable ammonium-based chalcogenometalate fluid that includes an ammonium-based chalcogenometalate precursor; an aqueous solvent; water; and a dopant; wherein, in the presence of heat, the printable ammonium-based chalcogenometalate fluid dissipates to form a transition metal dichalcogenide having the form MX₂ with the dopant distributed therethrough.

The present specification also describes a method that includes ejecting, from a nozzle, a first printable ammonium-based chalcogenometalate fluid comprising an ammonium-based chalcogenometalate precursor, an aqueous solvent, water, and a first dopant to form a layer of the first printable ammonium-based chalcogenometalate fluid; and heating the layer to dissipate the first printable ammonium-based chalcogenometalate fluid into a transition metal dichalcogenide having the form MX₂ with the first dopant distributed therethrough.

The present specification further describes a printing fluid cartridge that includes a reservoir to supply a printable ammonium-based chalcogenometalate fluid to a printing device, the printable ammonium-based chalcogenometalate fluid including an ammonium-based chalcogenometalate precursor having the form (NH4)2MX4, where: M is a transition metal; and X is a chalcogen; an aqueous solvent; water; and a dopant wherein, in the presence of heat, the printable ammonium-based chalcogenometalate fluid dissipates to form a transition metal dichalcogenide having the form MX₂ with the dopant distributed therethrough.

As used in the present specification and in the appended claims, the term “chalcogenometalate” may refer to transition metal thiometalates, or transitional metal-chalcogen compounds.

As used in the present specification and in the appended claims, the term “ammonium-based” may refer to a compound that includes the molecule NH₄.

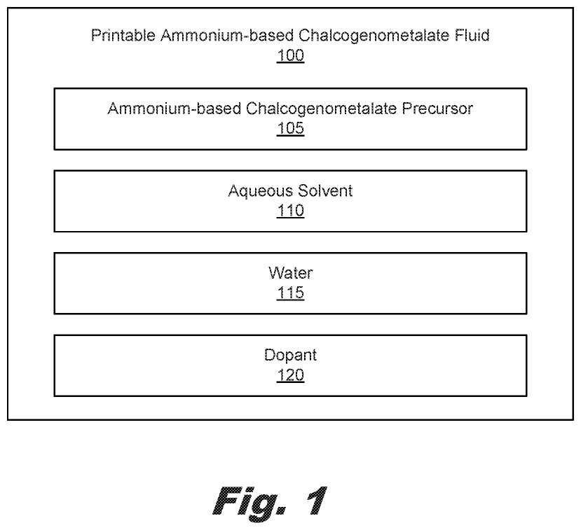

Turning now to the figures, FIG. 1 is a block diagram of a printable ammonium-based chalcogenometalate fluid (100) according to an example of the principles described herein. In some examples, the printable ammonium-based chalcogenometalate fluid (100) may be used as a printing fluid such as an ink. As with printing fluid, the printable ammonium-based chalcogenometalate fluid (100) is deposited on a substrate. The printable ammonium-based chalcogenometalate fluid (100) may be deposited on the substrate in any particular pattern in order to form, for example, the semiconductors as described herein. That is, the printable ammonium-based chalcogenometalate fluid (100) may be printable so as to form any shape, such as a logo, to form a semiconductor on a substrate in the same shape, i.e., the logo among other shapes. After deposition, the printable ammonium-based chalcogenometalate fluid (100) is treated such that a transition metal dichalcogenide (TMD) is left. The transition metal dichalcogenide is a 2D semiconductive material that is one atomic layer thick. As described herein in more detail, the ammonium-based chalcogenometalate fluid (100) may be printable and may be printed into any shape and print one any substrate.

The printable ammonium-based chalcogenometalate fluid (100) includes an ammonium-based chalcogenometalate precursor (105) that serves as the base of the fluid. The ammonium-based chalcogenometalate precursor (105) may, in an example, have the form (NH₄)₂MX₄. In this example, “M”, is a transition metal element as classified on a periodic table. Specific examples of transition metals of the present specification may include molybdenum and tungsten; however, other transition metals may be implemented as well. The “X” is a chalcogen element as classified on the periodic table. Examples of chalcogen elements include oxygen, sulfur, selenium, and tellurium. Specific examples of ammonium-based chalcogenometalate precursors (105) having the form (NH₄)₂MX₄ that may be found in the printable ammonium-based transition metal fluid (100) include ammonium tetrathiotungstate, (NH₄)₂WS₄, and ammonium tetrathiomolybdate, (NH₄)₂MoS₄.

While specific reference is made to particular ammonium-based chalcogenometalate precursors (105), a variety of ammonium-based chalcogenometalate precursors (105) may be used. These ammonium-based chalcogenometalate precursors (105) may be developed to form part of the printable ammonium-based chalcogenometalate fluid (100) or an ammonium-based chalcogenometalate printing fluid. These fluids may be printed directly on substrates such as a metallic substrate. In another example, the substrate may be a graphene substrate which has properties used in connection with electrical or electronic applications.

The printable ammonium-based chalcogenometalate fluid (100) may include an aqueous solvent (110). The aqueous solvent (110) dissolves the ammonium-based chalcogenometalate precursor (105) which may be formed into a powder form prior to mixing with the aqueous solvent (110). The aqueous solvent (110) may be any type of solvent including dimethyl sulfoxide (DMSO); dimethylformamide (DMF); N-methyl-20prrolidone (NMP); and 1,2-Hexanediol, among other-diol based solvents. While specific reference is made to particular aqueous solvents (110), a variety of aqueous solvents (110) may be used, which solvents may be selected based on the ammonium-based chalcogenometalate precursor (105) that is used.

The printable ammonium-based chalcogenometalate fluid (100) may include water (115). The aqueous solvent (110) and water (115) may be mixed in any variety of ratios to achieve a printable concentration of the printable ammonium-based chalcogenometalate fluid (100). For example, the aqueous solvent (110) and water (115) may be found in a ratio of 2 to 3:two parts aqueous solvent (110) to three parts water (115). However, any mixture ratio may be used to achieve different properties. In an example, these different properties may include different viscosities.

In some examples, the various components of the printable ammonium-based chalcogenometalate fluid (100), i.e., the ammonium-based chalcogenometalate precursor (105), the aqueous solvent (110), and the water (115), as well as the amounts and ratios of each component, may be selected based on the substrate onto which the printable ammonium-based chalcogenometalate fluid (100) is to be printed. The printable ammonium-based chalcogenometalate fluid (100) may be printed on numerous substrates. Examples of substrates that can be printed on include graphene, glass, polyethylene terephthalate, aluminum, quartz, sapphire, silicon, silicon dioxide, copper, nickel, ceramics, and gold. As described herein, the specific composition and mixture of the printable ammonium-based chalcogenometalate fluid (100) may be dependent upon the particular substrate selected.

The printable ammonium-based chalcogenometalate fluid (100) may also include a dopant (120). The dopant (120) may be any trace impurity element represented on the periodic table of elements that is added into the printable ammonium-based chalcogenometalate fluid (100) in order to alter the electrical or optical properties of the substance. In specific examples, the dopant (120) may be any one of F4TCNQ (C₁₂F₄N₄), tetracyanoquinodimethane (TCNQ); 1-Ethyl-3-methylimidazolium bis(trifluoromethylsulfonyl)imide ([EMIM]-[TFSI]), C₂₀H₂₈N₄O₄ (PDPP3T); C₄H₄S (thiophene); and dihydronicotinamide adenine dinucleotide (NADH). In a specific example, F4TCNQ (C₁₂F₄N₄) may be used as a p-type dopant. In an example, NADA may be used as an n-type dopant. Other dopants (120) include, but are not limited to, boron (B), arsenic (As), phosphorus (P), antimony (Sb), aluminum (Al), gallium (GA), sulfur (S), selenium (Se), tellurium (Te), silicon (Si), germanium (Ge), magnesium (Mg), zinc (Zn), cadmium (Cd), erbium (Er), europium (Eu), neodymium (Nd), holmium (Ho), and neodymium yttrium aluminum garnets (YAGs), among others.

In an example, the dopant (120) can enhance photocurrent and photoluminescence of the semiconductor materials giving the semiconductors a relatively better or new property. The method in which these example dopants (120) are applied to the semiconductor structures overcomes any inferiorities of, for example, a chemical vapor deposition (CVD) process. Indeed, the described methods presented herein achieve modulation in the optical and electrical properties of the materials deposited in the printable ammonium-based chalcogenometalate fluid (100). By adjusting the type of dopant (120) included within the printable ammonium-based chalcogenometalate fluid (100), properties of the semiconductor created may be enhanced or changed all together to achieve high carrier mobility. By including the dopant (120) within the printable ammonium-based chalcogenometalate fluid (100) the quantum efficiency of the semiconductor may be enhanced. In some examples, the electron transport, photocurrent, and photoluminescence of the semiconductor may be enhanced. Additionally, the control carrier density of the created semiconductor may increase the ability to control the optical properties of, for example, an LED. This may be done by shifting the Fermi level of the semiconductor. In order to do so, the dopant (120) is included with the printable ammonium-based chalcogenometalate fluid (100) and embedded within the finished semiconductor instead of being placed on a surface of the any layer within the semiconductor.

Additionally, by including the dopant (120) within the printable ammonium-based chalcogenometalate fluid (100), any layer of any semiconductor may be enhanced using the specific capabilities of that dopant (120) used. In an example, the printable ammonium-based chalcogenometalate fluid (100) with its dopant (120) may be printed on the surface using a printing device such as an inkjet printing device. This allows the specific printing of any dopant (120) material on any layer or portion of layer at any point. Additionally, such a printing process may be scaled to accommodate any individual size of project or semiconductor.

Following printing of the printable ammonium-based chalcogenometalate fluid (100) with its dopant (120), the printable ammonium-based chalcogenometalate fluid (100) is subject to a heating operation, wherein the aqueous solvent (110), water (115), and ammonium-based chalcogenometalate precursor (105) dissipate to form a transition metal dichalcogenide (TMD) having the form MX₂. For example, when the ammonium-based chalcogenometalate precursor (105) is ammonium tetrathiotungstate, (NH₄)₂WS₄, the resulting transition metal dichalcogenide is tungsten disulfide, WS₂, and when the ammonium-based chalcogenometalate precursor (105) is ammonium tetrathiomolybdate, (NH₄)₂MoS₄, the resulting transition metal dichalcogenide is molybdenum disulfide MoS₂. In some cases, the resulting transition metal dichalcogenide is transparent, such that a pattern or image on a substrate and underneath the TMD is visible. For example, a colored logo may be placed on the substrate and the printable ammonium-based chalcogenometalate fluid (100) disposed thereon such that it appears as if the logo itself is the semiconductive component.

Thus, using the printable ammonium-based chalcogenometalate fluid (100) described herein, any design or shape of ammonium-based chalcogenometalate fluid (100) can be printed with high accuracy, resulting in a TMD semiconductive element of the same design or shape. Moreover, the process does not implement specialized machinery. Indeed, in an example, the printable ammonium-based chalcogenometalate fluid (100) may be loaded into a printer cartridge or reservoir associated with an inkjet printing device and printed on the substrate.

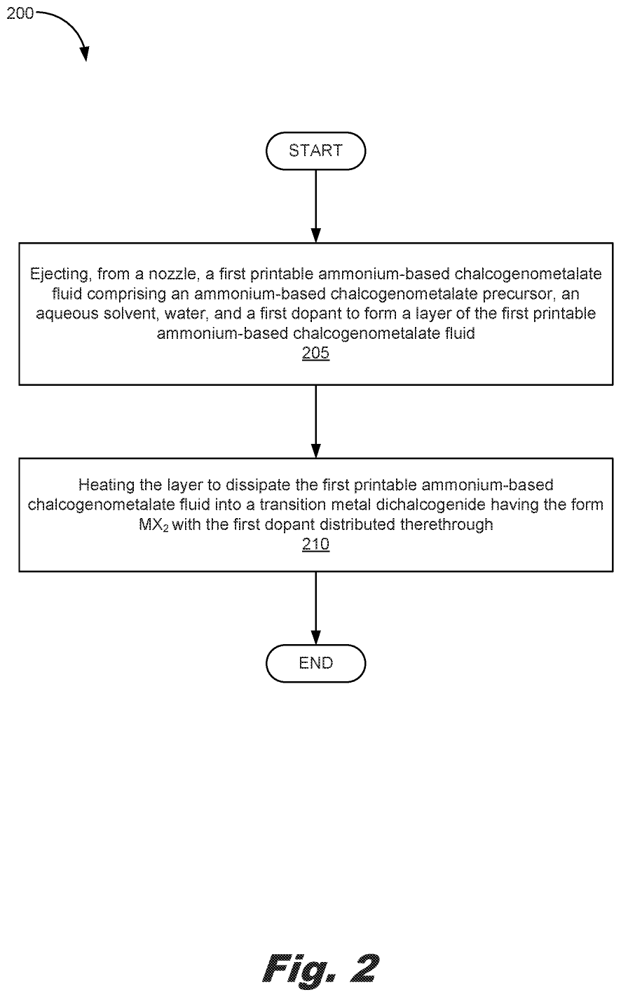

FIG. 2 is a flowchart showing a method (200) according to an example of the principles described herein. The method (200) may include ejecting (205), from a nozzle, a first printable ammonium-based chalcogenometalate fluid comprising an ammonium-based chalcogenometalate precursor, an aqueous solvent, water, and a first dopant to form a layer of the first printable ammonium-based chalcogenometalate fluid. In an example, the printable ammonium-based chalcogenometalate fluid (100) described herein with its dopant (120) may be maintained in a reservoir associated with a printing device. This reservoir may be independent of the printing device or within a print material cartridge. Other examples of providing the printable ammonium-based chalcogenometalate fluid (100) with its dopant (120) to a printing device with its nozzles are contemplated in the present description.

As described herein, the printable ammonium-based chalcogenometalate fluid (100) includes an ammonium-based chalcogenometalate precursor (105), an aqueous solvent (110), water (115), and a dopant (120). The different components may be mixed in any amounts, and any ratio, based on any number of factors, such as desired viscosity, printer characteristics, printer cartridge characteristics, and the substrate on which the printable ammonium-based chalcogenometalate fluid (100) is to be deposited. The dopant (120) may be any type of dopant as described herein. These dopants (120) may increase the photocurrent and photoluminescence of the semiconductor materials giving the semiconductors a relatively better or new property.

The method (200) may include heating (210) the layer to dissipate the first printable ammonium-based chalcogenometalate fluid into a transition metal dichalcogenide having the form MX₂ with the first dopant distributed therethrough. During the heating (210) process, the printable ammonium-based chalcogenometalate fluid (FIG. 1, 100) may break down to form a transition metal dichalcogenide, which is a semiconductive component. More specifically, after printing, the substrate with the printable ammonium-based chalcogenometalate fluid (FIG. 1, 100) disposed thereon is heated (210) to a temperature of between 180 and 500 degrees Celsius for about 10 minutes under nitrogen flow. In a specific example, where the ammonium-based transition chalcogenometalate fluid (100) is ammonium tetrathiomolybdate, (NH₄)₂MoS₄, once heated above 200 degrees Celsius, the printable ammonium-based chalcogenometalate fluid (FIG. 1, 100) breaks down into a combination of molybdenum trisulfide, MoS₃, two molecules of ammonia 2(NH₃) and hydrogen sulfide, H₂S. Once the temperature is above 500 degrees Celsius up to 900 degrees Celsius, the molybdenum trisulfide further decomposes into molybdenum disulfide, MoS₂, and sulfur, S, and becomes crystalline, which molybdenum disulfide is a 2D semiconductive material. In this fashion, a 2D semiconductive material having the form MX₂, is printed on a substrate. Printing this printable ammonium-based chalcogenometalate fluid (100) provides greater flexibility and simplicity in forming 2D semiconductive materials and expands the use of such materials more fully into some technical areas and introduces it into use in other technical areas.

In an example of the present specification, the ejection (205) and heating (210) of the deposited layers may be completed any number of times iteratively ejecting (205) and heating (210) these layers. In a specific example, doping a base layer of the printable ammonium-based chalcogenometalate fluid (100), and then annealing that base layer to make it hard and resistant to mixing with a subsequent layer of ejected (205) printable ammonium-based chalcogenometalate fluid (100). As the subsequent layer of printable ammonium-based chalcogenometalate fluid (100) is deposited onto the hardened base layer any of the unique dopants (120) may be added to provide the unique properties for any given layer. In this example, neither the subsequent layer nor the dopants (120) added to the subsequent layer would interact with the base layer because the base layer has already been hardened in the heating (210) process. In any example presented herein, any number of layers may be deposited with intervening heating (205) of each layer. Further, through the use of the methods and systems described herein, the semiconductor material may be doped with the dopant (120) while the heating process is conducted thereby completing these two processes in a single process. This increases the speed at which any semiconductor is created thereby decreasing the costs associated with the manufacturing of any semiconductive device. Still further, by selective alteration of the amount of dopants within the printable ammonium-based chalcogenometalate fluids, the ratio of dopants within layers of the created semiconductor may be better refined.

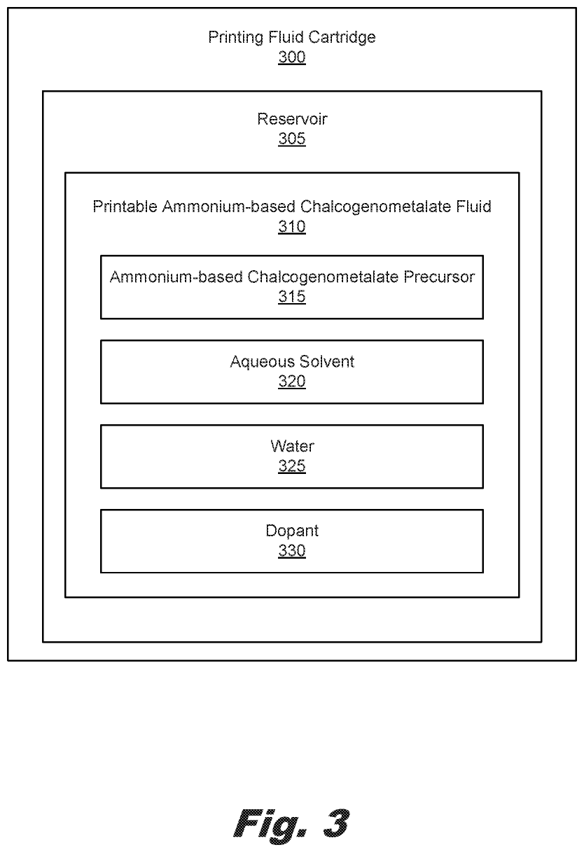

FIG. 3 is a block diagram of a printing fluid cartridge (300) according to an example of the principles described herein. In an example, the printing fluid cartridge (300) may include a reservoir (305) to maintain any amount of printable ammonium-based chalcogenometalate fluid (300) therein. As described herein, the printable ammonium-based chalcogenometalate fluid (310) may include an ammonium-based chalcogenometalate precursor (315), an aqueous solvent (320), water (325), and the dopant (330) as described herein.

In an example, the ammonium-based chalcogenometalate precursor (315) may have the form of (NH₄)₂MX₄, where M is a transition metal and X is a chalcogen. Specific examples of transition metals include molybdenum and tungsten; however, other transition metals may be implemented as well. The X is a chalcogen atom as indicated on the periodic table. Examples of chalcogens include oxygen, sulfur, selenium, and tellurium. Specific examples of ammonium-based chalcogenometalate precursors (315) having the form (NH₄)₂MX₄ that may be found in the printable ammonium-based transition metal fluid (310) include ammonium tetrathiotungstate, (NH₄)₂WS₄, and ammonium tetrathiomolybdate, (NH₄)₂MoS₄.

In an example, the printing fluid cartridge (300) may include a printhead having a number of nozzles to carry out at least a part of the functionality of ejecting the printable ammonium-based chalcogenometalate fluid (310). The printhead may include any number of components for ejecting the printable ammonium-based chalcogenometalate fluid (310). For example, the printhead may include a number of nozzles arranged in any configuration. A nozzle may include an ejector, a firing chamber, and an orifice. The orifice may allow printable ammonium-based chalcogenometalate fluid (310) to be deposited onto a surface, such as a substrate. The firing chamber may include a small amount of fluid. The ejector may be a mechanism for ejecting fluid through the orifice from the firing chamber, where the ejector may include a firing resistor or other thermal device, a piezoelectric element, or other mechanism for ejecting fluid from the firing chamber.

For example, the ejector may be a firing resistor. The firing resistor heats up in response to an applied voltage. As the firing resistor heats up, a portion of the fluid in the firing chamber vaporizes to form a bubble. This bubble pushes liquid fluid out the orifice and onto the substrate. As the vaporized fluid bubble pops, fluid is drawn into the firing chamber from the reservoir (305), and the process repeats. In this example, the printhead may be a thermal inkjet (TIJ) printhead.

In another example, the ejector may be a piezoelectric device. As a voltage is applied, the piezoelectric device changes shape which generates a pressure pulse in the firing chamber that pushes a fluid out the orifice and onto the substrate. In this example, the printhead may be a piezoelectric inkjet (PIJ) printhead.

The printhead and printing device may also include other components to carry out various functions related to fluidic ejection. For example, the printing device may include a processor that controls the various components of the printing device. As described herein, the printing device and the printable ammonium-based chalcogenometalate fluid (310) allows for easy deposition of the fluid, and the formation of a solid semiconductive component. Accordingly, any shape may be reproduced and may form the semiconductive component of an electrical circuit or electronic component.

In an example, the printing fluid cartridge (300) may be part of a printing system that includes a heating device. The heating device may heat the individual layers of printable ammonium-based chalcogenometalate fluid (310) after deposition onto a substrate. The heating device may include any type of heating device either incorporated into the substrate or separate from the substrate and/or printing system. The heating device may be any type of heating device such as an electric resistive device or heat lamp. As described herein, the heating device may heat any individual layer to between 180 and 500 degrees Celsius in order to solidify or otherwise harden the layer previous to the deposition of any subsequent layer of printable ammonium-based chalcogenometalate fluid (310) being deposited.

The printing system may be implemented with any type of computing device. Examples of computing devices include servers, desktop computers, laptop computers, personal digital assistants (PDAs), mobile devices, smartphones, gaming systems, and tablets, among other electronic devices.

To achieve its desired functionality, the computing device may include various hardware components. Among these hardware components may be a number of processors, a number of data storage devices, a number of peripheral device adapters, and a number of network adapters. These hardware components may be interconnected through the use of a number of busses and/or network connections. In one example, the processor, data storage device, peripheral device adapters, and a network adapter may be communicatively coupled via a bus.

The hardware adapters in the computing device enable the processor of the computing device to interface with various other hardware elements, external and internal to the computing system including the printing device with its printing fluid cartridge (300). For example, the peripheral device adapters may provide an interface to input/output devices, such as, for example, display device, a mouse, or a keyboard. The peripheral device adapters may also provide access to other external devices such as an external storage device, a number of network devices such as, for example, servers, switches, and routers, client devices, other types of computing devices, and combinations thereof.

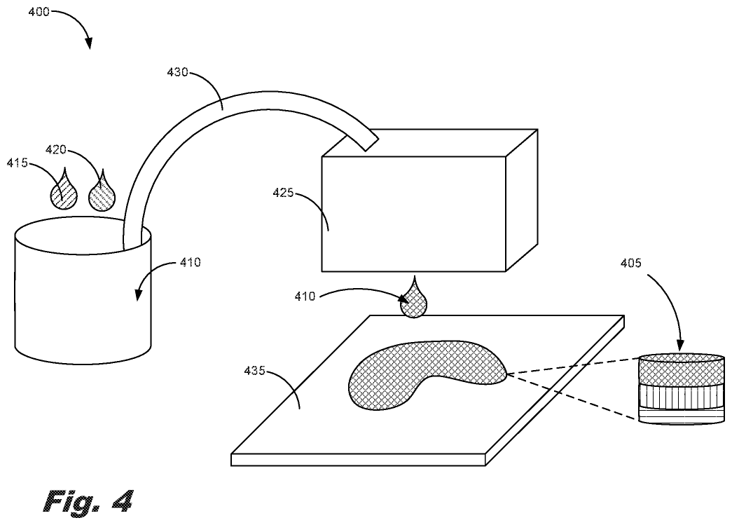

FIG. 4 is a block diagram of a process flow (400) used to form a semiconductor device (405) according to an example of the principles described herein. The process flow (400) may start with mixing a printable ammonium-based chalcogenometalate fluid (410) by adding a dopant (420) with an ammonium-based chalcogenometalate precursor (415) into a reservoir associated with a printing device (425). The mixed printable ammonium-based chalcogenometalate fluid (410) may be provided to the printing device (425) via a tube (430). The printhead (425) may eject an amount of printable ammonium-based chalcogenometalate fluid (410) onto a substrate (435). Heat may be applied to the deposited printable ammonium-based chalcogenometalate fluid (410) forming the semiconductor (405) as described herein.

Aspects of the present system and method are described herein with reference to flowchart illustrations and/or block diagrams of methods, apparatus (systems) and computer program products according to examples of the principles described herein. Each block of the flowchart illustrations and block diagrams, and combinations of blocks in the flowchart illustrations and block diagrams, may be implemented by computer usable program code. The computer usable program code may be provided to a processor of a general-purpose computer, special purpose computer, or other programmable data processing apparatus to produce a machine, such that the computer usable program code, when executed via, for example, the processor of the computing device, printing system, or other programmable data processing apparatus, implement the functions or acts specified in the flowchart and/or block diagram block or blocks. In one example, the computer usable program code may be embodied within a computer readable storage medium; the computer readable storage medium being part of the computer program product. In one example, the computer readable storage medium is a non-transitory computer readable medium.

The preceding description has been presented to illustrate and describe examples of the principles described. This description is not intended to be exhaustive or to limit these principles to any precise form disclosed. Many modifications and variations are possible in light of the above teaching.

What is claimed is:

1. A printable ammonium-based chalcogenometalate fluid, comprising:
an ammonium-based chalcogenometalate precursor;
an aqueous solvent;
water; and
a dopant;
wherein, in the presence of heat, the printable ammonium-based chalcogenometalate fluid dissipates to form a transition metal dichalcogenide having the form MX₂ with the dopant distributed therethrough.

2. The fluid of claim 1, wherein the ammonium-based chalcogenometalate precursor has the form (NH₄)₂MX₄ wherein:
M is a transition metal; and
X is a chalcogen.

3. The fluid of claim 1, wherein the ammonium-based chalcogenometalate precursor is selected from the group consisting of:
ammonium tetrathiotungstate; and
ammonium tetrathiomolybdate.

4. The fluid of claim 1, wherein the dopant is selected from the group consisting of:
F₄TCNQ;
TCNQ;
[EMIM]-[TFSI];
PDPP3T;
thiophene; and
NADA.

5. The fluid of claim 1, wherein the transition metal dichalcogenide is transparent.

6. The fluid of claim 1, wherein the aqueous solvent and the water are present in a 2-to-3 ratio.

7. A method comprising:
ejecting, from a nozzle, a first printable ammonium-based chalcogenometalate fluid comprising an ammonium-based chalcogenometalate precursor, an aqueous solvent, water, and a first dopant to form a layer of the first printable ammonium-based chalcogenometalate fluid; and
heating the layer to dissipate the first printable ammonium-based chalcogenometalate fluid into a transition metal dichalcogenide having the form MX₂ with the first dopant distributed therethrough.

8. The method of claim 7, wherein ejecting, from the nozzle, the first printable ammonium-based chalcogenometalate fluid comprises:
heating an ejector within a firing chamber of the nozzle;
forming a vapor bubble within the firing chamber of the nozzle, which vapor bubble ejects an amount of the printable ammonium-based chalcogenometalate fluid through an opening in the nozzle.

9. The method of claim 7, further comprising:
ejecting, from the nozzle, a second printable ammonium-based chalcogenometalate fluid comprising an ammonium-based chalcogenometalate precursor, an aqueous solvent, water, and a second dopant onto the substrate to form a layer of the second printable ammonium-based chalcogenometalate fluid; and
heating the second layer to dissipate the second printable ammonium-based chalcogenometalate fluid into a transition metal dichalcogenide having the form MX₂ with the second dopant distributed therethrough.

10. The method of claim 9, wherein the second printable ammonium-based chalcogenometalate fluid has a different composition than the first printable ammonium-based chalcogenometalate fluid.

11. The method of claim 7, wherein a composition of the first printable ammonium-based chalcogenometalate fluid is selected based on the substrate on which the first printable ammonium-based chalcogenometalate fluid is to be ejected on.

12. The method of claim 7, wherein the substrate is selected from the group consisting of: graphene, glass, polyethylene terephthalate, aluminum, quartz, sapphire, silicon, silicon dioxide, copper, nickel, ceramics, and gold.

13. The method of claim 7, further comprising:
forming the ammonium-based chalcogenometalate precursor by combining a fluid having the form (NH₄)₂MO_{y} with a gas having the form H₂X where:
M is the transition metal;
Y is a numeric value;
X is a chalcogen selected from the group consisting of:
sulfur;
selenium; and
tellurium.

14. A printing fluid cartridge, comprising:
a reservoir to supply a printable ammonium-based chalcogenometalate fluid to a printing device, the printable ammonium-based chalcogenometalate fluid comprising:
an ammonium-based chalcogenometalate precursor having the form (NH₄)₂MX₄, where:
M is a transition metal; and
X is a chalcogen;
an aqueous solvent;
water; and
a dopant
wherein, in the presence of heat, the printable ammonium-based chalcogenometalate fluid dissipates to form a transition metal dichalcogenide having the form MX₂ with the dopant distributed therethrough.

15. The printing fluid cartridge of claim 14, comprising a number of nozzles to eject an amount of the printable ammonium-based chalcogenometalate fluid, each nozzle comprising:
a firing chamber to hold the amount of printable ammonium-based chalcogenometalate fluid;
an orifice; and
an ejector to eject the amount of printable ammonium-based chalcogenometalate fluid through the orifice.
